(19) United States
(12) Patent Application Publication
(10) Pub. No.: US 2026/0109641 A1
(43) Pub. Date: Apr. 23, 2026

(54) SOLAR CONTROL GLASS WITH OPTICAL ABSORBER

(71) Applicant: Glas Trösch AG, Bützberg (CH)

(72) Inventors: Aneliia WÄCKERLIN, Aarau (CH); Angela HUNZIKER, Binningen (CH)

(21) Appl. No.: 19/121,740

(22) PCT Filed: Nov. 2, 2022
(86) PCT No.: PCT/EP2022/080528

§ 371 Date: Apr. 16, 2025

(51) Int. Cl. C03C 17/36; H10F 77/42

(52) U.S. Cl. CPC C03C 17/366; C03C 17/3626; C03C 17/3644; C03C 17/3649; H10F 77/42; C03C 2217/211; C03C 2217/212; C03C 2217/216; C03C 2217/252; C03C 2217/256; C03C 2217/261; C03C 2217/281; C03C 2217/78; C03C 2218/154

(57) ABSTRACT

The invention refers to a glass substrate and a solar control layer stack on at least one face of the glass substrate, the layer stack comprising:—at least one IR-reflective coating (II) comprising a silver containing layer (2′):—at least one absorption coating (IV) comprising an optical absorption layer (4) sandwiched and in direct contact to both between two silicon nitride layers (4′, 4″), the absorption layer (4) consisting of a sub-stoichiometric metal nitride MeNₓ, a sub-stoichiometric metal oxide MeO_{y}, or a mixture thereof MeNₓO_{y}, where Me is at least one of an element from the transition metal group V or/and VI of the periodic system of the elements:—a base coating (I) comprising at least one base layer (1) deposited directly on the substrate, and consisting of a silicon nitride or a metal oxide and thereby forming an inner layer of the solar control stack.

### TECHNICAL FIELD OF THE INVENTION

The current invention relates to a glass substrate with a solar control layer stack on at least one face of the glass substrate according to the claims.

### DESCRIPTION OF THE RELATED ART

Many glass substrate comprising silver containing solar control stacks are known from the state of the art. As an example, WO 2020/164735 A1 of the same applicant discloses a scratch resistant functional product comprising at least one metallic silver inclusive layer, a transition metal (TM) inclusive layer and a hydrogen containing DLC (DLCH) layer in direct contact to a final surface of the TM inclusive layer. Scratch resistant layer(s) as disclosed there, can be useful also for layer systems of the present invention as will be described later.

When it comes to absorber coatings or layers it has to be mentioned that many optical absorber systems are already known from solar collector materials. Some of them are also applied in glazings for vehicles or buildings. The main function of such coatings is a reduction of transmission, of reflection, as well as neutralizing the color of reflection.

A problem with any optically absorptive coating is re-emission of the heat, i.e. high emissivity, leading to an increased heat transfer into the vehicle/building, characterized by an increased g-value or a respectively increased solar factor. Therefore, it is of crucial importance to have solar selectivity, i.e. high absorption in the a visible range and a high reflection in the thermal range.

A further disadvantage of well-known absorber materials like Ti, Zr, Hf layers is a strong dependence of optical and conductive properties depending on the nitrogen content, e.g., titanium nitride shifts to a golden color with an increasing nitrogen content. The targeted optical absorber properties however should be as neutral as possible in a process relevant range of nitridation to ensure the same optical appearance with slightly varying process parameters in the production line(s). At the same time materials like Ti, Zr, Hf-based layers have low k-values of the extinction coefficient index, leading to an increased layer thickness and respective higher material and energy consumption to achieve the required absorption, i.e. the desired transmission level.

When it comes to near stoichiometrically nitride or oxidized materials an essential reduction of the sputter rate and in many cases process instabilities can be observed making production process difficult to control.

A further disadvantage of many known combinations of adsorption layers and neighboring dielectric layers being in direct contact with each other is a poor performance of the dielectric layer as a chemical barrier layer towards the absorbing layer and therewith a high thickness which is necessary to ensure the chemical and optical stability during the sputter process of the succeeding layer(s), or even more critical during thermal processing of glass (toughening, bending, lamination, etc.)

### Definitions

A solar layer stack according to the present invention comprises all layers and coatings within a solar control layer stack which is usually arranged on one side of an essentially flat substrate. Wherein coatings are functional sub-stacks comprising at least one layer providing a respective functionality. Examples of the coatings are IR-reflective, absorption, antireflective layer stacks, base, scratch resistant, or separating coatings.

Inner/below respectively outer/above/upper with reference to the layer stack, the coating or the single layer means that the coating, the layer or the side of the layer is arranged at or directed to the side facing toward the substrate (inner side) respectively toward the surface (outer side) of the stack, coating, or layer. Me^{I}, Me^{II}, . . . refers to a one, two . . . valent metal.

### SUMMARY OF THE INVENTION

It is a task of the current invention to avoid the disadvantages of the state of the art as described above and to provide glasses with solar control layer stacks of high chemical and optical stability which are able to hold respective optical properties given by the coating process throughout following mechanical and thermal processes as well as over the whole life cycle of the glass product.

Therefore it is a specially task of the current invention to provide a substrate coated with a solar control layer stack having a transmission level to enable a superior high absorption in the visible range and a respective high reflection in the thermal (IR) range, and at the same time ensure an identical optical appearance with slightly varying process parameters in the production line(s), which can be a neutral optical appearance or a respective appearance in a defined color.

This task is solved by a glass substrate with the features of claim 1. Further embodiments of the device/process are defined by the features of the depending claims.

A glass substrate according to the invention can be a flat glass product like architectural glass, a composite glass pane, which is a laminated glass product, or a car or a plane window, and has a solar control layer stack on at least one face of the glass substrate, the solar control layer stack comprising:
at least one IR-reflective coating comprising a silver containing layer;
at least one absorption coating comprising an optical absorption layer sandwiched and in direct contact to both between two silicon nitride layers, which can be one or both an Al-doped silicon layer, thereby when normalized to Silicon (i.e. Si=1) can be in the range as defined by the formula SiNₓAl_{y} with x=1-1.4 (i.e. 1 to 1.4) and y=0-0.35 (i.e. 0 to 0.35). The absorption layer consists of a sub-stoichiometric metal nitride MeNₓ, a sub-stoichiometric metal oxide Mely, or a mixture thereof MeNₓO_{y}, where Me is at least one of an element from the group V or/and VI of the periodic system of the elements. Preferably the at least one absorption coating is arranged in a direction towards the surface of the layer stack above or below any IR-reflective coating;
a base coating comprising at least one base layer deposited directly on the substrate (i.e. in contact to the surface of the substrate), and consisting of a silicon nitride or a metal oxide and thereby forming an inner layer of the solar control stack. Both the silicon nitride or the metal oxide can be doped with Aluminium, and the metal of the metal oxide can be a Me^{II}, like Sn or Zn, a Me^{IV}, like Sn, Ti, or Zr, or a Me^{V}, like Nb.

In an embodiment of the invention the silver containing layer of the IR-reflective coating can be sandwiched and in direct contact to both between a ZnO or ZnO:Al layer on the substrate side forming an inner layer of the IR-reflective coating and a NiCr or a TiO₂ layer on the side of the silver containing layer which is directed towards the surface, and a further ZnO, a SnZnO or a SnO₂ layer, or respective Al-doped layer, thereby preferably a further ZnO, respectively ZnO:Al layer, each in direct contact with the NiCr or the TiO₂ layer forming an outer layer of the IR-reflecting coating in a direction towards the surface of the layer stack.

With the IR-reflective coating NiCr can be used in all cases also for glasses which have to be annealed in the following whereat TiO₂ should not be used when further heat treatment should be necessary. The NiCr layer of the IR-reflective coating can be a nickel rich NiCrₓ layer, e.g. 0.1≤x_{Cr}≤0.5, preferably 0.2≤x_{Cr}≤0.3. The TiO₂ layer of the IR-reflective coating can be first deposited sub-stoichiometric, e.g. up to minus 20 at. %, preferably up to minus 5 at. % of the stoichiometric O-ratio, and in the following being nearly or even fully oxidized by the sputtering of the subsequent further ZnO layer.

The Al concentration in the ZnO:Al of the IR-reflective coating can be as defined in the following ZnAlxOy, where x=0-0.3, e.g. 0-0.1 (an Al concentration below 5 at %, e.g. 0-2.5 at % is preferred), and y=0.8-1.2. SnZnO can be expressed in an inventive embodiment as normalized to Sn as SnZnxOy, e.g with x=1-4, especially x=1-2.5, y=2-4, or more preferred y=2.5-3.5.

Whenever ZnO or ZnO:Al layers having a thickness large than 10 nm should be needed, it can be preferably to use stacks of respective alternating ZnO/SnZnO or ZnO:Al/SnZnO:Al layers to avoid crystallisation.

It is important to mention that silver or silver containing layers are always grown directly on a zinc oxide layer and always protected, i.e. followed directly by a blocking layer, which can be any metallic or sub-stoichiometric transition metal layer. Preferentially NiCr, or TiOₓ, can be used. Alternatively dielectric layers can be doped as e.g., Si₃N₄:Al and ZnO:Al, or mixed layers as TiZrO₂, TiNbO₂ may be applied. Zn-containing layers may be ZnO:Al, SnZnO.

In any embodiment of the invention the base coating may comprise at least one of a nitride or oxide layer of Si, Ti, Sn, Zn, SnZn, Nb, Zr, thereby preferably Si, Ti, Sn, Zn or SnZn, or a stack of such nitride or oxide layers different with respect to the metallic or semiconductive element(s) in consecutive layers. The base coating thereby may consist of at least one of a Si₃N₄, TiO₂, TiZrO₂, SnO₂, ZnO, SnZnO, ZrO₂, Nb₂O₃, or a Nb₂O₅ layer, or an adhesion layer system consisting of at least two of the respective layers e.g. SnO₂/TiO₂, Si₃N₄/SnZnO/TiO₂, SnO₂/SnZnO/TiO₂. All species may comprise also sub-stoichiometric compounds of up to −10%, with reference to the elements nitrogen or oxygen. The base layer may contain a high refractive index metal oxide or a low refractive index metal oxide or silicon nitride as single layer, or a mixture of respective alternating high and low reflective layers, e.g., to supply an antireflective function to the layer stack.

In an embodiment of the invention the base layer can be the inner silicon nitride layer of the absorption coating, whereby the absorption coating forms an inner absorption coating and a base layer at the same time.

In any embodiment of the invention at least one of the silicon nitride layers, the ZnO, the further ZnO, the SnZnO, the SnO₂, and/or the nitride or oxide layer of Si, Ti, Sn, Zn, SnZn, Nb, Zr can be an Al-doped layer, e.g. a Si₃N₄:Al, ZnO:Al, SnO₂:Al, SnZnO:Al, . . . layer. Thereby the concentration of Al can be in the following ranges for Si₃N₄:Al, ZnO:Al.

SiNₓAl_{y}:1≤x≤1.4,0≤y≤0.35,e.g. SiN_{1.33}Al_{0.18};

ZnAlₓO_{y}:X=0-0.3,e.g.0-0.1,y=0.8-1.2;

In an embodiment of the invention the solar control layer stack may comprise a terminal scratch resistant coating, the scratch resistant coating comprising at least a compound layer consisting of the transition metals (TM), e.g., titanium and/or zirconium compound, with the non-metal(s) oxygen and/or carbon. The ratio of the TM, especially Ti and/or Zr, and oxygen can be up to TM:O 1:2, e.g. TiO₂ or (TiZr)O₂. The ratio of the TM and carbon can be TM:C, especially Ti:C or (TiZr):C from 1:1 to 1:6, or 50-85 at. % C, e.g. 1:3. The ratio of the metals within the TM can be expressed by the formula TiZrₓ, where x=0-1, e.g. 0.1-0.5. Top coat TiZrO₂ can be any TM oxide, preferably TiZrO₂, ZrO₂, or TiO₂.

In a further embodiment of the invention the scratch resistant coating consists of a titanium zirconium carbide layer followed in a direction towards the surface and in direct contact to the titanium zirconium carbide layer by a hydrogen containing diamond-like carbon (DLCH) layer. This substrate may form an end-product or a pre-product for further tempering, e.g. after the substrate has been trimmed to its final size, as the handling during the trimming step(s) requires a particularly robust surface.

Despite of the fact that the terminal scratch resistant coating can be a single layer of any TM oxide, TiZrO₂, ZrO₂, or TiO₂ are preferred. In an embodiment of the invention the scratch resistant coating is a titanium zirconium oxide layer, e.g. TiZrO₂. This coating may form the terminal surface of the final glass product after a pre-product comprising a two layers scratch resisting coating of titanium zirconium carbide and DLC, as described above has been further manufactured, e.g. by a thermal glass strengthening step, a bending step, a cutting step, a trimming step, a laminating or other assembling step, and the like and has been further subjected to a final temper step.

In a further embodiment of the invention the IR-reflective coating may follow directly onto the absorption coating, e.g, the inner zinc oxide layer of the IR-reflective coating can be in direct contact to the outer silicon nitride coating of the absorption coating.

In a scratch resistant embodiment of the invention a further silicon nitride layer, which can be a Si₃N₄ layer, can be sandwiched and in direct contact to both between the terminal layer of the IR-reflecting coating and the scratch resistant coating. As an example the terminal layer can be the further zinc oxide layer, a SnZnO or a SnO₂ layer of an IR-reflecting coating, the latter, coming from the substrate side may consist of a ZnO/Ag/NiCr/ZnO (or SnZnO or SnO₂) layer stack. The terminal zinc oxide layer may contact the further silicon nitride layer, the latter optionally may further contact the titanium zirconium carbide or the titanium zirconium oxide layer of a respective scratch resistant coating.

In a further embodiment of the invention the absorption coating or a further absorption coating may follow directly onto the IR-reflective coating or a further IR-reflective coating. In this configuration the inner silicon nitride coating of the absorption or further absorption coating can be in direct contact to an outer zinc oxide (or SnZnO or SnO₂) layer of the IR-reflective or further IR-reflective coating. In this case the outer silicon nitride layer of the absorption coating or of the further absorption coating can be in direct contact to the optional scratch resistant coating as described above with respect the further silicon nitride layer.

The absorption coating can be an inner absorption coating, e.g., integrated in direct contact with the glass under the (inner) IR-reflective coating comprising a (inner) silver containing layer. The absorption coating or a further absorption coating can be positioned above the (inner) IR-reflective coating, e.g., between the inner silver layer and a scratch resistant layer, or in case of two IR-reflective coatings between the inner and outer IR-reflective coatings. However preferably below the inner/first IR-reflective coating and/or above the outer/(second, third, . . . ) IR-reflective coating.

In any embodiment of the invention the absorption layer can be a sub-stoichiometric metal nitride MeNₓ and the stoichiometric value x can be: 0.1≤x≤1, especially 0.1≤x≤0.7, especially 0.1≤x≤0.45. Thereby the absorption layer can be a sub-stoichiometric metal nitride MeNₓ or a sub-stoichiometric metal oxide Mely.

In any embodiment of the invention Me can be one of Mo, Ta, or W or a mixture thereof, e.g, the sub-stoichiometric nitride, oxide or oxynitride can be MONₓO_{y}, TaNₓO_{y} Or WNₓO_{y}. In any embodiment of the invention at least one of the two silicon nitride layers and/or the further silicon nitride layer can be doped with aluminium. Thereby the doped SiN:Al of the silicon nitride or of the further silicon nitride can have the following composition SiNₓAl_{y}, with 1≤x≤1.4, 0≤y≤0.35, e.g. SiN_{1.33}Al_{0.18}.

In a further embodiment of the invention two preferably identical IR-reflective coatings are arranged consecutively, whereat the IR-reflective coatings can be separated by a separating coating being in direct contact to both IR-reflective coatings and may comprise or consist of another silicon nitride layer, another zinc oxide, another tin oxide, or another zinc tin oxide layer, e.g. a Si₃N₄, a SnO₂, a ZnO, or a ZnSnO layer. The separating coating may also consists of a silicon nitride layer followed and in direct contact with a zinc tin oxide layer, whereat the silicon nitride layer is in direct contact with the terminal zinc oxide (or SnZnO or SnO₂) layer of the inner IR-reflective coating and the zinc tin oxide layer is in direct contact with the inner zinc oxide layer of the outer IR-reflecting coating. Further separating coatings consisting or comprising at least one of titanium oxide and/or tin-zinc oxide may be arranged between an IR-reflective coating and an absorption coating. Alternatively any separating coating can be designed as an antireflective (AR) coating comprising at least one high or low index material, or respective alternating high and low index materials. Thereby high index materials may be TiO₂, ZrO₂, TiZrO₂, Nb₂O₃, Nb₂O₅, and low index materials may be SiO₂, Al₂O₃, ZnO, ZnSnO, SnO₂, Si₃N₄.

In any embodiment of the invention the silver containing layer can be a silver layer.

In any embodiment of the invention the difference Δk between the extinction coefficients of the absorption coating measured at 780 nm and at 380 nm, Δk=k₇₈₀−k₃₈₀ can be:

$$\vert 0.4 < △ k < 1 \text{.0} \vert , preferably : \vert 0.5 \leq △ k \leq 0.8 \vert$$

In any embodiment of the invention the extinction coefficient k₅₅₀ of the MeNₓO_{y} layer measured at a wavelength of 550 nm can be:

$$1.5 < {k}_{550} < 4.2 , preferably : 1.5 \leq {k}_{550} \leq 4.2$$

In any embodiment of the invention the specific electric resistivity R of the MeNₓO_{y} layer can be:

$$R < 600 μΩ * cm , preferably R < 400 μΩ * cm$$

The features of the above-mentioned embodiments of the device/process can be used in any combination, unless they contradict each other.

### BRIEF DESCRIPTION OF THE DRAWINGS

Embodiments of the current invention are described in more detail in the following with reference to the FIGURES. These are for illustrative purposes only and are not to be construed as limiting. It shows

FIG. 1 scheme of a solar control layer stack

FIG. 2 extinction coefficients versus wavelength

FIG. 3 extinction coefficient versus nitrogen flow per KW target power

FIG. 4 sputter rate versus nitrogen flow per kW target power

FIG. 5 resistivity versus nitrogen flow per kw target power

FIG. 6 XPS sputter depth profile

FIG. 7 fit curves for quantification of XPS profile

### DETAILED DESCRIPTION OF THE INVENTION

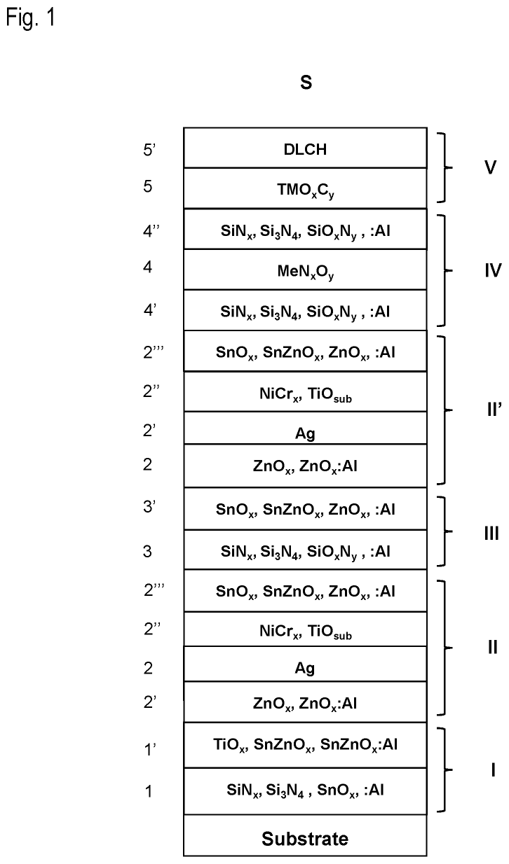

FIG. 1 shows an exemplary scheme of a solar control layer stack S deposited on a surface of a glass substrate. The layer stack comprises coming from the surface of the substrate a base coating I consisting of two base layers 1,1′ of respective materials as given in the drawing. In this case the silicon nitride or tin oxide base layer 1, forms an adhesion layer towards the substrate. The base coating I is followed by a first IR-reflective coating II comprising a silver IR-reflective layer 2. A separating coating III consisting of two separating layers 3,3′ is provided between the first IR-reflective coating II and the second IR-reflective coating II′, both having the same four-layer IR-reflective design (2′/2/2″/2′″). An absorption coating IV follows on coating II′, whereat the absorption coating IV consists of a metal nitride layer 4 sandwiched between two silicon nitride or silicon oxynitride layers 4′, 4″ of the same composition. The utmost outer scratch resistant coating V again is a two layers coating consisting of a transition metal (TM) carbo oxide layer 5 and an amorphous hydrogenated diamond-like carbon (DLCH) layer 5′ which forms the terminal layer of the layer stack towards atmosphere.

Layer materials can be one of the materials as given with the respective layer. When “:Al” follows after a comma, any of the forgoing materials can be doped with aluminium. “Me” of the absorption layer 5 can be Mo, Ta or W. Transition metals “TM” in respective layer 5 can be Ti and Zr.

Further examples for different combinations of the respective coatings and layers are given in table 1, examples 1 to 14.

It should be emphasized that with reference to examples 1, 8, 9, and 11 to 14, base layer 1 giving the adhesion to the substrate is formed by the inner silicon nitride layer 4′ of the adsorption coating, which means that in this case a one layer base coating I consisting of the inner silicon nitride layer 4′ which at the same time is base line 1 is integrated in an adsorption coating and in direct contact to the substrate surface. Therewith no separate base coating is necessary with such layer types.

Examples 1-8 show stacks comprising one IR-reflective coating, while examples 9-14 show stacks comprising two IR-reflective coatings. Absorption coatings can be foreseen above, see examples 2-7 and 10, below, see example 1 and 9, or on both sides of the IR-stack(s), see examples 8 and 11-14. Separation between two successive IR-stacks is provided by a one or two layered separation coating which can be applied between any successive IR-stack. Further separation coatings can be provided between an IR-coating and the scratch resistant coating (example 1 and 9), between an absorption coating and an IR-reflective coating as shown with example 14.

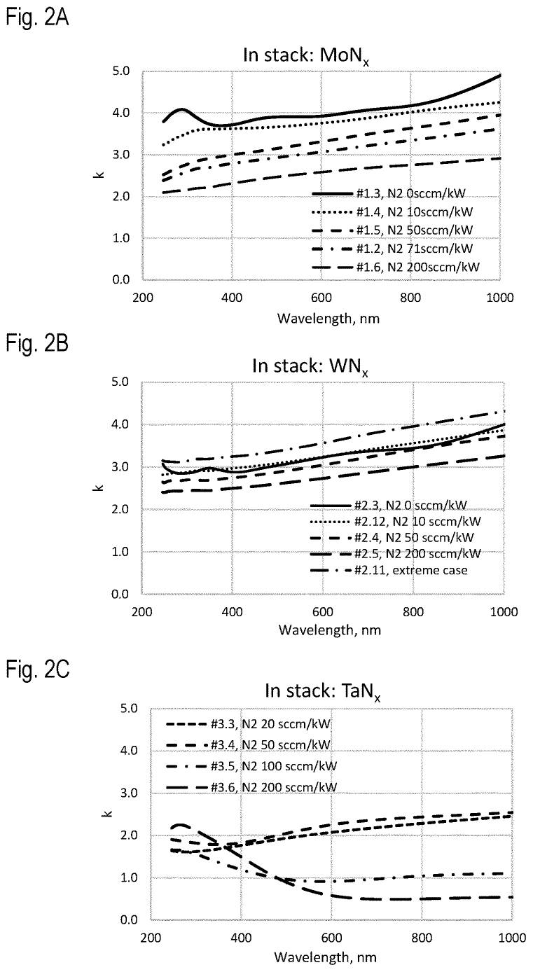

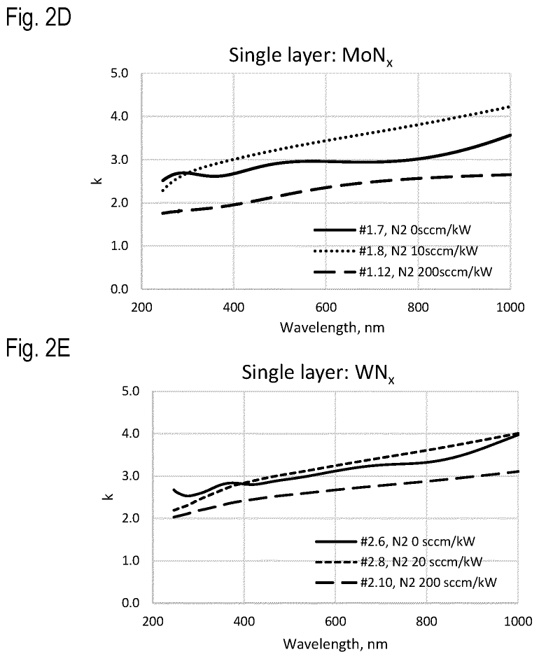

FIGS. 2-7 refer to specific experiments which have been performed with three selected absorber materials (MONₓ, TaNₓ, WNₓ), which when deposited sub-stoichiometrically showed an outstanding performance in their optical and process relevant material properties (see Table 2B).

Details about the respective deposition parameters can be found in Table 2A. In Table 4 the process parameters for the whole stack of the solar control glass as applied in an industrial coater with a target size of approx. 380 cm is described. Process parameters for the production of the absorbing stack are in line “Si₃N₄ or Si₃N₄:Al” and line “MeNₓO_{y}”.

For the chemical and optical characterization each optical absorbing film of interest has been sandwiched in a stack between two SiN:Al layers, as the surrounding layers have a strong impact on the properties of a thin film with a thickness <20 nm. All the stacks (material and layer thicknesses, as well as process parameters) used for chemical and optical characterization, are listed in Table 2A. The “#-column” has four group of samples 1 to 4, referring to Mo— (1), W— (2), and Ta-absorbers (3), and the glass substrate (4), followed by a respective sample number.

Chemical composition was measured by X-Ray photoelectron spectroscopy (XPS), optical properties were measured by ellipsometry and optical spectroscopy, thickness of stack was measured by stylus profilometry.

XPS sputter depth profile was performed though repetitive cycles: ion sputtering and consequent XPS measurement.

XPS measurements have been performed with the following parameters: monochromatic x-ray beam (Al Kα edge), spot size 100 μm, pass energy 26 eV (energy resolution FWHM=0.6 eV (Ag 3d_{5/2}), in scanning mode). Sputtering was performed with Zalar rotation to ensure the best depth resolution, with Ar+ ions, 1 kV 2×2, sputter time e.g. 1 min per cycle. Atomic concentrations (at. %) of elements were measured across the whole stack (Si₃N₄:Al/MeNₓO_{y}/Si₃N₄:Al) and the chemical composition of the MeNₓO_{y} was defined in the middle of the film. The chemical composition of the film is defined as follows: x=N (at. %)/Me (at. %), y=0 (at. %)/Me (at %), therefore MeNₓO_{y}.

For modelling the optical constants n(λ) and k(λ), ellipsometric measurement (Ψ(λ) and Δ(λ) for the angles 55°-75° with step 5° were combined with optical spectroscopy (UV-Vis-NIR Spectrophotometer), film thickness has been determined by stylus profilometer for each layer of the stack, which for the measurement had been deposited separately as a single layer on a test glass, and then hold fix during the following modelling (CompleteEase Software). B-Spline and Gen-Osc models were used to model the absorber.

FIG. 2A, 2B, 2C show the dependency of the extinction coefficient k depending on the wavelength compared for MONₓ, WNₓ, respectively TaNₓ. Each of the FIGURES shows curves of the respective MeNₓ as reactively sputtered with different nitrogen amounts, which refer to respectively different MeNₓ stoichiometries as mentioned below. Sample numbers (# x.y) refer to Table 2A. The extinction coefficient is a good measure for the possible optical absorption of a layer or layer system. A neutral optical appearance can be efficiently achieved when the coefficient of the optical absorption k does not show a strong k-variation in the visible wave-range λ. This was the case with low nitrogen flows from 5 to 75 sccm/kW, especially from 8 to 20 sccm/kW. These amounts refer to sub-stoichiometric MeNₓ species with x from 0.2 to 0.7. Therewith the shape of the k-curve is homogeneous, almost linear and the variation of K is small. Also the highest extinction coefficient could be achieved in the same flow range, whereat best results could be reached for MoNₓ, in a range of 10±5 sccm/kW. Important to mention that the optimal reactive gas flow per kW power (sccm/kW) is strongly dependent on the coater size and geometry, pumping efficiency, length of sputtering target and power on the sputtering target used. Therefore the decisive description of the absorbing layer is at the end the stoichiometry MeNx of the sputtered layer, as defined e.g. with XPS.

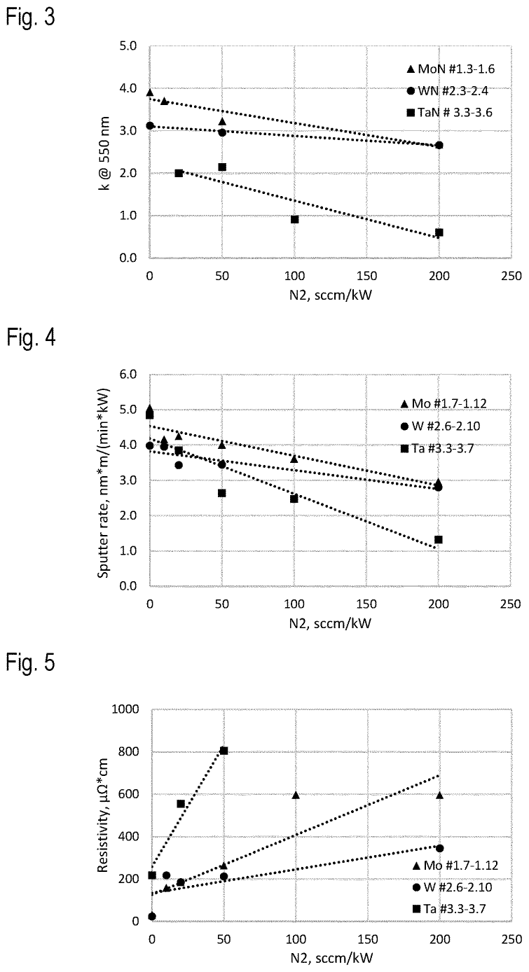

FIG. 3 shows the extinction coefficient at 550 nm of respectively sandwiched MONₓ, WNₓ, TaNₓ adsorbers versus nitrogen flow per kW power. With all 3 target materials (Mo, W, Ta) sputter rate started to diminish significantly with increasing nitrogen flow, at the latest from 50 sccm/kW and higher. FIG. 4-5 show sputter rate and the resistivity of MONₓ samples #1.7-1.12, WNₓ samples #2.6-2.10, and TaNₓ samples #3.3-3.7 depending on the N₂ amount (for respective nitrogen flow values in sccm/kW, see Table 2A, column 4).

Specific electrical resistivity is also a good indicator of the absorptive properties and thereby gives a possibility to set-up and/or control the reactive sputter process as shown in FIG. 5. This means, the lower the electrical resistivity is, the higher is the extinction coefficient k (see FIG. 3). For process efficiency, lower resistivity values are preferred as well, as can be seen in the range between 10 and 75 sccm/kW for MON and 10-50 sccm/kW for WN.

It can be seen that absolute k-values of W and especially—of Mo as shown exemplarily in FIG. 3, can be set significantly higher than respective values of well known and documented materials as for example of TiNₓ (k (550 nm) which is 2.1 according to J. Pflüger, J. Fink. Determination of optical constants by high-energy, electron-energy-loss spectroscopy (EELS), in Handbook of optical constants of solids II, Edward D. Palik, ed. Academic Press, 1991. pp. 293-310; 2) J. Pflüger, J. Fink, W. Weber, K. P. Bohnen, G. Crecelius. Dielectric properties of TiCx, TiNx, VCx, and VNx from 1.5 to 40 eV determined by electron-energy-loss spectroscopy, Phys. Rev. B 30, 1155-1163 (1984)). Ta substoichiometric nitrides perform similar as TiNₓ.

Moreover, surprisingly a favorable N-range to obtain highest possible optical absorption in visible range has been found. Surprisingly, layers with a very low N content (MeNₓ, x≤0.7, e.g. 0.04≤0.1) in most cases show an even higher optical absorption than could be observed with pure metallic layers in the case of WNₓ and of MONₓ, see FIG. 2B, #2.12, 2D, #1.8, 2E, #2.8. Such nitride layers with a low N content always had a higher optical absorption than layers with a high N content (MeNₓ, x>0.7) or stoichiometric metal nitride layers, see FIG. 2A-2E. Improvement of optical absorbing properties (vs metal) due to low N content is exemplified in single layers (Mo, W), and in a stack in case of W. Note, in an extreme case, where a metallically deposited absorbing layer is <5 nm, the following reactive gas containing process to deposit silicon nitride introduces a low amount of N to the metallic layer giving rise to an even higher optical absorption coefficient k (see as an example stack number #2.11 in Table 2A with d_{WNx}=4.0 nm and x=0.08, and the respective curve in FIG. 2B). This can be seen in comparison to a stack with a thicker metallic film (e.g. d>5 nm, see as an example stack number #2.3 in Table 2A with d_{WNx}=8.0 nm and x=0.003, and the respective curve in FIG. 2B), or compared to a pure metallic layer without following Si₃N₄ process (see as an example stack number #2.6 in Table 2A, with d_{WNx}=55.3 nm and x=0, as shown in FIG. 2E). The most stable absorption layer coating with reference to chemical and mechanical properties can be achieved when the dielectric layer is Si₃N₄ (optionally doped, e.g., with Al) and is in direct contact with the absorbing layer from both sides. The minimal thickness of the respective silicon nitride sandwich layers to protect the absorbing layer during tempering processes is d>8 nm, e.g. 8-30 nm, especially 10-20 nm.

As the thermal expansion coefficient of Si-containing sandwich layers is expected to be virtually identical to the one of Mo, W, Ta being <7.5 μm/(m*K), with Si: 2.6 μm/(m*K), Mo: 4.8 μm/(m*K), W: 4.5 μm/(m*K), Ta: 6.6 μm/(m*K), and shear modulus is similar >60 GPa, with Mo: 120 GPa, W: 161 GPa, and Ta: 69 GPa, even though the exact values depend on the chemical composition (stoichiometry of the metal nitride) and electronic structure [Ozsdolay, B., “WNx and MoNx Layers: Elastic Properties and Crystal Structure”, PhDT, 2016; Kindlund, H., Sangiovanni, D., Petrov, I., Greene, J. E, Hultman, L., (2019), “A review of the intrinsic ductility and toughness of hard transition-metal nitride alloy thin films”, Thin Solid Films, 688, 137479; W. Chen, J. Z. Jiang, “Elastic properties and electronic structures of 4d- and 5d-transition metal mononitrides”, Journal of Alloys and Compounds, Volume 499, Issue 2,2010, Pages 243-254; C. Kral et al., “Critical review on the elastic properties of transition metal carbides, nitrides and carbonitrides”, Journal of Alloys and Compounds 265 (1998) 215-233], respectively stacked adsorbing coatings are perfectly mechanically matched for solar control layer stacks on glass substrates which are subject to heat-treatment or shear stress during washing of the coated glass pane. Such adsorption coatings can be applied preferably below and/or above the IR-reflecting stack(s), i.e., between the substrate and lowest or inner IR-reflecting stack, and/or between the highest or outer IR-reflecting stack and the terminal (outer) surface of the solar control layer stack towards atmosphere. When the terminal surface of the layer stack is formed by an optional scratch resistant coating a respective single layer or inner layer of the scratch resistant coating can be in direct contact with the outer silicon nitride layer of the adsorption coating.

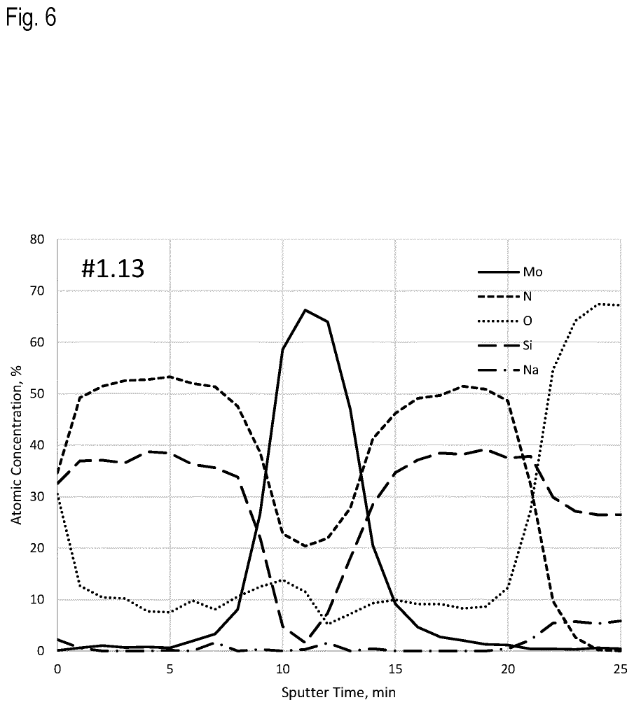

In FIG. 6 an XPS sputter depth profile of the three layers stack of an adsorption coating according to sample #1.13 is shown. From there the respective distribution of the elements Mo, N, Si within the three layers stack and O, Si, Na within the glass substrate can be seen in dependency of the sputter time, which refers to the sputter-etch time of the etching device used for sputtering away (=etching) the sample surface before the XPS analysis. The analysis starts at the left (0 min) on the surface of the sample and ends after 25 minutes of sputter etching of the sample with Ar⁺ ions as described above, in some nm depth within the surface of the glass substrate. The Mo-peak of the MONₓ layer, i.e. the optical absorbing film with x=0.31, is sandwiched between the two Si₃N₄ layers showing a respective higher nitrogen concentration.

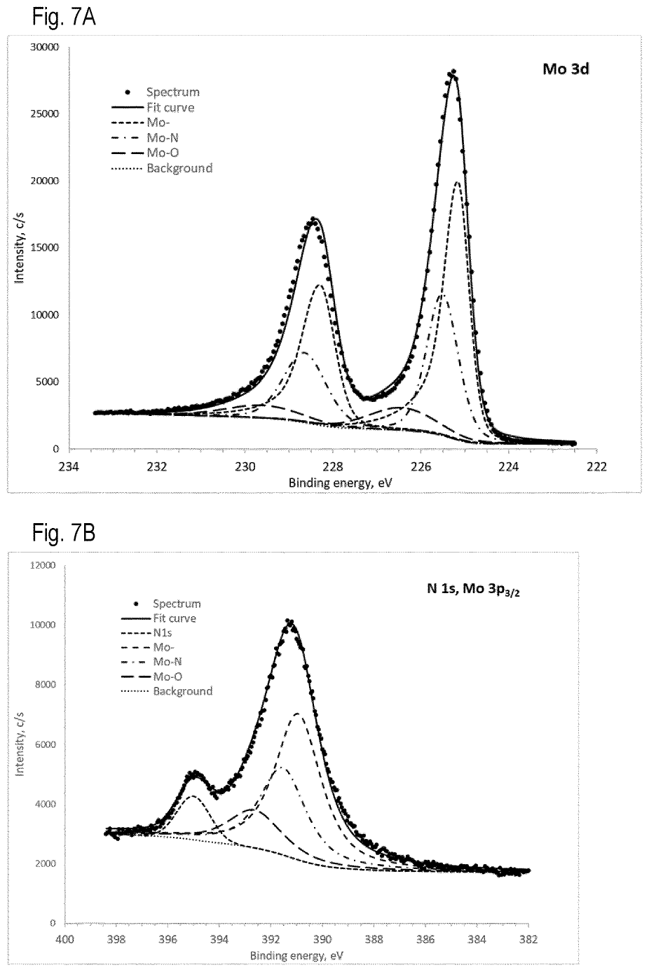

The two graphs in FIG. 7A, 7B show XPS spectra for MONₓ sample #1.13 at the maximum of the Mo-intensity signal (see FIG. 6) and a respective fit curve for the quantification of the atomic concentrations. Where the graph in FIG. 7A shows the Mo3d core-level spectrum and the fit curve in a binding energy region between about 223-232 eV and the graph in FIG. 7B shows the Mo3p_{3/2} core-level spectrum and the fit curve for the N1s in the region from about 385-399 eV. Both FIGURES show a very good correlation of the fit curve (solid line), representing the sum of the bond contributions (Mo, Mo—N, Mo—O different dashed lines), and the measured curve (filled circles).

### REFERENCE SIGNS LIST

S layer stack
I base coating
   1,1′ layers of the base coating
   1 base layer (can be integrated in the absorption coating)
II IR-reflective coating
   2, 2′, 2″, 2′″ layers of the IR-reflective coating
   2 silver containing layer
III separation coating
   3,3′ layers of the separation coating
IV absorption coating
   4,4′ layers of the absorption coating
V scratch resistant coating
   5,5′ layers of the scratch resistant coating
   5 TM containing layer
   5′ DLCH layer (optional)

TABLE 1
Exemplary solar layer stacks according to the invention

| 1 | 2 | 3 | 4 | 5 | 6 | 7 | 8 | 9 | 10 | 11 | 12 | 13 | 14 | type |
|---|---|---|---|---|---|---|---|---|---|---|---|---|---|---|
| | | | | | | | | | | | | | DLC | Scrat. |
| | | | | | | | | | | | | | TiZrCₓ | resis. |
| | | | | | | | | | | | | DLC | Si₃N₄ | Further |
| | | | | | | | | | | | DLC | TiZrCₓ | MoNₓ | absorpt. |
| | | | | | | | | | | TiZrO₂ | TiZrCₓ | Si₃N₄ | Si₃N₄ | |
| | | | | | | | | | | Si₃N₄ | Si₃N₄ | MoNₓ | ZnO | IR-reflective |
| | | | | | | | | TiZrO₂ | TiZrO₂ | MoNₓ | MoNₓ | Si₃N₄ | NiCr | |
| | | | | | | | | Si₃N₄ | Si₃N₄ | Si₃N₄ | Si₃N₄ | ZnO | Ag | |
| | | | | | | | | ZnO | MoNₓ | ZnO | ZnO | NiCr | ZnO | Se- |
| | | | | | TiZrO₂ | TiZrO₂ | TiZrO₂ | NiCr | Si₃N₄ | NiCr | NiCr | Ag | ZnSnO | parat. |
| | | | | TiZrO₂ | Si₃N₄ | Si₃N₄ | Si₃N₄ | Ag | ZnO | Ag | Ag | ZnO | Si₃N₄ | |
| TiZrO₂ | TiZrO₂ | TiZrO₂ | TiZrO₂ | Si₃N₄ | MoNₓ | MoNₓ | MoNₓ | ZnO | NiCr | ZnO | ZnO | ZnSnO | ZnO | IR-reflective |
| Si₃N₄ | Si₃N₄ | Si₃N₄ | Si₃N₄ | MoNₓ | Si₃N₄ | Si₃N₄ | Si₃N₄ | ZnSnO | Ag | ZnSnO | ZnSnO | Si₃N₄ | NiCr | |
| ZnO | MoNₓ | MoNₓ | MoNₓ | Si₃N₄ | ZnO | ZnO | ZnO | ZnO | ZnO | ZnO | ZnO | ZnO | Ag | |
| NiCr | Si₃N₄ | Si₃N₄ | Si₃N₄ | ZnO | NiCr | NiCr | NiCr | NiCr | ZnSnO | NiCr | NiCr | NiCr | ZnO | |
| Ag | ZnO | ZnO | ZnO | NiCr | Ag | Ag | Ag | Ag | ZnO | Ag | Ag | Ag | TiO2 | Furth.se- |
| ZnO | NiCr | NiCr | NiCr | Ag | ZnO | ZnO | ZnO | ZnO | NiCr | ZnO | ZnO | ZnO | ZnSnO | parat. |
| Si₃N₄ | Ag | Ag | Ag | ZnO | TiO₂ | TiO₂ | Si₃N₄ | Si₃N₄ | Ag | Si₃N₄ | Si₃N₄ | Si₃N₄ | Si₃N₄ | Absorpt. |
| MoNₓ | ZnO | ZnO | ZnO | TiO₂ | SnZnO | SnZnO | MoNₓ | MoNₓ | ZnO | MoNₓ | MoNₓ | MoNₓ | MoNₓ | |
| Si₃N₄ | Si₃N₄ | TiO₂ | SnO₂ | SnO₂ | SnO₂ | Si₃N₄ | Si₃N₄ | Si₃N₄ | Si₃N₄ | Si₃N₄ | Si₃N₄ | Si₃N₄ | Si₃N₄ | |
| Substrat | Substrat | Substrat | Substrat | Substrat | Substrat | Substrat | Substrat | Substrat | Substrat | Substrat | Substrat | Substrat | Substrat | |

TABLE 2A
Properties and production parameters of absorption layer stacks.
The stacks were produced by RF reactive sputtering process, working with
metal target, Ar process gas and N₂ reactive gas, whereat the sputter target
dimension: 748.5 mm × 87.5 mm (approx. 660 cm²).

| | | Thickness | N2 | | Glas, | MeNₓ |
|---|---|---|---|---|---|---|
| # | Stack materials* | [nm | [sccm/kW] | [kW] | [mm] | x = |
| 1.1 | Si₃N₄/MONₓ/Si₃N₄ | 9.8/0.9/13.8 | 71 | 0.7 | 5.8 | n.m. |
| 1.2 | Si₃N₄/MONₓ/Si₃N₄ | 9.8/4.6/13.8 | 71 | 0.7 | 5.8 | 0.53 |
| 1.3 | Si₃N₄/MONₓ/Si₃N₄ | 9.8/7/13.8 | 0 | 1 | 5.8 | 0 |
| 1.4 | Si₃N₄/MONₓ/Si₃N₄ | 9.8/7/13.8 | 10 | 1 | 5.8 | n.m. |
| 1.5 | Si₃N₄/MONₓ/Si₃N₄ | 9.8/7/13.8 | 50 | 1 | 5.8 | 0.5 |
| 1.6 | Si₃N₄/MONₓ/Si₃N₄ | 9.8/7/13.8 | 200 | 1 | 5.8 | n.m. |
| 1.7 | Mo | 75.5 | 0 | 1 | 3.8 | 0 |
| 1.8 | MONₓ | 62.9 | 10 | 1 | 3.8 | 0.25 |
| 1.9 | MONₓ | 90.0 | 20 | 1 | 3.8 | n.m. |
| 1.10 | MONₓ | 84.9 | 50 | 1 | 3.8 | 0.47 |
| 1.11 | MONₓ | 65.5 | 100 | 1 | 3.8 | 0.69 |
| 1.12 | MONₓ | 44.8 | 200 | 1 | 3.8 | 0.75 |
| 1.13 | Si₃N₄/MONₓ/Si₃N₄ | 12/5.5/13.8 | 29 | 0.7 | 5.8 | 0.31 |
| 2.1 | Si₃N₄/WNₓ/Si₃N₄ | 14/1.2/11 | 50 | 1 | 5.8 | n.m. |
| 2.2 | Si₃N₄/WNₓ/Si₃N₄ | 12/5.2/12 | 50 | 1 | 5.8 | n.m. |
| 2.3 | Si₃N₄/WNₓ/Si₃N₄ | 12/8.0/12 | 0 | 1 | 5.8 | 0.003 |
| 2.4 | Si₃N₄/WNₓ/Si₃N₄ | 12/8.0/12 | 50 | 1 | 5.8 | 0.2 |
| 2.5 | Si₃N₄/WNₓ/Si₃N₄ | 12/8.0/12 | 200 | 1 | 5.8 | 0.33 |
| 2.6 | Si₃N₄/W | 55.3 | 0 | 1 | 3.8 | 0 |
| 2.7 | WNₓ | 65.9 | 10 | 1 | 3.8 | n.m. |
| 2.8 | WNₓ | 66.7 | 20 | 1 | 3.8 | 0.14 |
| 2.9 | WNₓ | 86.2 | 50 | 1 | 3.8 | n.m. |

*All Si₃N₄ layers were sputtered with 33.3 sccm/kW. Si Target is Al doped (8-10 wt. %).
n.m. not measured

TABLE 2A
Continuation

| | | | N2 | | | |
|---|---|---|---|---|---|---|
| | Stack | Thickness | [sccm/ | | Glas, | MeNx |
| # | materials* | [nm] | kW] | [kW] | [mm] | x = |
| 2.10 | WNₓ | 77.7 | 200 | 1 | 3.8 | n.m. |
| 2.11 | Si₃N₄/WNₓ/Si₃N₄ | 12/4.0/12 | 0 | 1 | 5.8 | 0.08 |
| 2.12 | Si₃N₄/WNₓ/Si₃N₄ | 12/8.0/12 | 10 | 1 | 5.8 | 0.09 |
| 3.1 | Si₃N₄/TaNₓ/Si₃N₄ | 11/2.4/11 | 50 | 1 | 5.8 | n.m. |
| 3.2 | Si₃N₄/TaNₓ/Si₃N₄ | 11/10.0/11 | 50 | 1 | 5.8 | n.m. |
| 3.3 | Si₃N₄/TaNₓ/Si₃N₄ | 6.7/17.6/8.2 | 20 | 1 | 5.8 | 0.57 |
| 3.4 | Si₃N₄/TaNₓ/Si₃N₄ | 6.7/16.1/8.2 | 50 | 1 | 5.8 | 0.76 |
| 3.5 | Si₃N₄/TaNₓ/Si₃N₄ | 6.7/15.1/8.2 | 100 | 1 | 5.8 | n.m. |
| 3.6 | Si₃N₄/TaNₓ/Si₃N₄ | 6.7/8.1/8.2 | 200 | 1 | 5.8 | 0.88 |
| 3.7 | Ta | 22 | 0 | 1 | 5.8 | 0 |
| 4 | Float glass | | — | | 5.8 | n.m. |

*All Si₃N₄ layers were sputtered with 33.3 sccm/kW. Si Target is Al doped (8-10 wt. %).
n.m. not measured

TABLE 2B
Properties of absorption layer stacks as used with table 1

| | | Thickness, | BRA | | | | RA | | | | TA | | | |
|---|---|---|---|---|---|---|---|---|---|---|---|---|---|---|
| # | Stack | nm | Y | L* | a* | b* | Y | L* | a* | b* | Y | L* | a* | b* |
| 1.1 | Si₃N₄/MONₓ/Si₃N₄ | 9.8/0.9/13.8 | 12.3 | 41.7 | −1.3 | −5.4 | 15.1 | 45.8 | −0.9 | −4.6 | 73.9 | 88.9 | −0.7 | 2.2 |
| 2.1 | Si₃N₄/WNₓ/Si₃N₄ | 14/1.2/11 | 11.3 | 40.1 | −1.3 | −5.0 | 15.5 | 46.3 | −0.9 | −4.7 | 71.0 | 87.5 | −0.7 | 2.2 |
| 3.1 | Si₃N₄/TaNₓ/Si₃N₄ | 11/2.4/11 | 12.5 | 41.9 | −1.8 | −5.2 | 16.5 | 47.6 | −1.0 | −5.7 | 72.5 | 88.2 | −0.9 | 3.8 |
| 1.2 | Si₃N₄/MONₓ/Si₃N₄ | 9.8/4.6/13.8 | 11.4 | 40.3 | −1.3 | −3.6 | 21.4 | 53.4 | −0.5 | −0.1 | 43.8 | 72.1 | −0.4 | 0.9 |
| 2.2 | Si₃N₄/WNₓ/Si₃N₄ | 12/5.2/12 | 12.3 | 41.6 | −1.4 | −3.5 | 24.5 | 56.6 | −0.5 | −1.4 | 39.5 | 69.1 | −0.4 | 1.7 |
| 3.2 | Si₃N₄/TaNₓ/Si₃N₄ | 11/10.0/11 | 13.7 | 43.7 | −1.3 | −5.9 | 27.2 | 59.1 | −0.3 | −2.8 | 41.7 | 70.7 | −0.9 | 2.5 |
| 4 | Float glass | | | | | | | | | | | | | |

| | RGS 55° | | | | | | | | ε ± |
|---|---|---|---|---|---|---|---|---|---|
| # | Y | L* | a* | b* | Abs, % | ΔT, % | ΔE_{T} | ΔE_{BR} | 0.005 |
| 1.1 | 18.0 | 49.5 | −1.0 | −2.8 | 11.0 | 0.4 | 0.3 | 1.4 | 0.801 |
| 2.1 | 17.0 | 48.2 | −0.9 | −2.5 | 13.5 | 0.8 | 0.5 | 1.7 | 0.826 |
| 3.1 | 17.8 | 49.2 | −1.3 | −2.3 | 11.0 | 1.2 | 0.6 | 1.0 | 0.825 |
| 1.2 | 16.5 | 47.7 | −0.9 | −1.8 | 34.8 | 1.1 | 0.8 | 0.8 | 0.768 |
| 2.2 | 17.5 | 48.8 | −1.1 | −1.8 | 36.0 | 0.5 | 0.4 | 0.8 | 0.739 |
| 3.2 | 17.9 | 49.4 | −1.0 | −3.4 | 31.1 | −0.2 | 1.6 | 1.8 | 0.801 |
| 4 | | | | | | | | | 0.836 |

TABLE 3
Glass with scratch resistant solar control layer stack (exemplary stack according to example 7 and respective variations):

| coating | Layer-Material | d [nm] | Composition |
|---|---|---|---|
| scratch | DLCH | 1-100, e.g. 5-20, 8-12 | DLCH (without metal), e.g. ta-C:H |
| resistant | TiZrCₓ, TiZrOₓC_{y} | 1-20, e.g. 2-6 | TM:C 1:1-1:6, e.g. 1:3 (or 25-85 at. % C) |
| | | | TM, e.g. TiZrₓ, x = 0-1, e.g. 0.1-0.5 |
| absorption | Silicon nitride or aluminum | 1-100, e.g. 3-60, 5-30 | Si₃N₄ or Si₃N₄:Al, N can be stoichiometric or sub-st. up to −15%, |
| | doped silicon nitride | | e.g. SiNₓAl_{y}, x = 1-1.4, y = 0-0.35, e.g. SiN_{1.33}Al_{0.18} |
| | Absorption layer: Me^{V}NₓO_{y} | 0.1-50, e.g. 0.4-10 | O, N sub- stoichiom. (5-60 at. %), e.g. MoN_{0.1-1}, MoN_{0.1-0.6}, |
| | (Me: Mo, Ta, W) | | WN_{0.1-1}, WN_{0.1-0.6}, TaN_{0.1-1}, TaN_{0.1-0.6}. Whereat O might be present |
| | | | till 20 at. %, preferentially < 10 at. %. |
| | Silicon nitride or aluminum | 1-100, e.g. 3-60, 5-30 | Si₃N₄ or Si₃N₄:Al, N can be stoichiom. or sub-st. up to −15 at. %, |
| | doped silicon nitride | | Al content variable, e.g. SiNₓAl_{y}, x = 1-1.4, y = 0-0.35, SiN_{1.33}Al_{0.18} |
| separating | ZnO, SnO₂, SnZnO or | coat: <150, e.g. <100 | O can be stoichiom. or sub-st. (up to −15 at. %), Al 0-20 at. % e.g. |
| | ZnO:Al, SnO₂:Al, | single layer: 0.5-100, | ZnAlₓO_{y}, x = 0-0.3, e.g. 0-0.1, y = 0.8-1.2, e.g. ZnO_{0.8-1}Al_{0.04-0.06} |
| | SnZnO:Al, SiNₓAl_{y} | e.g. 4-30, 4-20 | SnZnₓO_{y}, x = 1-4, e.g. x = 1-2.5, y = 2-4, e.g. y = 2.5-3.5, |
| | | | SnZn₂O₃ |
| IR-reflective | ZnO, SnO₂, SnZnO or | 0.5-100, e.g. 4-30, 4-20 | O can be stoichiometric or sub-st. (up to −15 at. %), Al 0-20 at. % |
| | ZnO:Al, SnO₂:Al, | | e.g. ZnAlₓO_{y}, x = 0-0.3, e.g.0-0.1, y = 0.8-1.2, e.g. ZnO_{0.8-1}Al_{0.04-0.06} |
| | SnZnO:Al, SiNₓAl_{y} | | SnZnₓO_{y}, x = 1-4, e.g. x = 1-2.5, y = 2-4, e.g. y = 2.5-3.5, |
| | | | SnZn₂O₃. |
| | NiCrₓ (mandatory for | 0.3-20, e.g. 0.5-10 | metallic, or oxidized. O can be stoichiometric or sub-st. NiCrₓ |
| | tempering), or TiO_{sub} (no temp.) | | containing layer, metallic ratio e.g. 0.1 ≤ x_{cr} ≤ 0.5 (see descr.) |
| | Ag | 1-30, e.g. 5-20 | metallic |
| | ZnO, SnZnO or ZnO:Al, | 0.5-30, e.g. 3-15 | O can be stoichiom. or sub-st. (up to −15 at. %), Al 0-20 at. %, e.g. |
| | SnZnO:Al | | ZnAlₓO_{y}, x = 0-0.3, pref. 0-0.1, y = 0.8-1.2; e.g. ZnO_{0.8-1}Al_{0.04-0.06} |
| | | | SnZnₓO_{y}, x = 1-4, pref. 1-2.5, y = 2-4, pref. 2.5-3.5, e.g. |
| | | | SnZn₂O₃. |
| base | Dielectric, e.g .: TiO₂, | 1-60, e.g. 1-15, 3-7 | TiO₂, or TiZrₓO₂, x = 0-1, e.g. 0.2-0.5 |
| | TiZrO₂, ZrO₂, NbOₓ | | |
| | SnO₂, SnZnO, ZnO or | 1-100, e.g. 5-30, 5-15 | O can be stoichiometric or sub-st. (up to −15 at. %) |
| | SnZnO:Al, ZnO:Al | | |
| | Silicon nitride, titanium oxide, | 1-60, e.g. 1-40, 5-30 | Si₃N₄ or Si₃N₄:Al, SiNₓAl_{y}, x = 1-1.4, y = 0-0.35, e.g. SiN_{1.33}Al_{0.18}, |
| | silicon metal nitrides, -oxides, | | SiNₓO_{y}Me₂ (Me: Nb, Ti, Zr), x = 0-1.4, y = 0-2, z = 0-2. |
| | -oxinitides (Me: Al, Nb, Ti, Zr) | | |
| Substr. | Glass | 1-20 [mm] | Any type of window (architectural, automotive) glass, or |
| | | | composite glass pane |

TABLE 4
Process parameters for different layer materials at the industrial coater:

| Layer-Material | Process | Process parameters per 1 cathode |
|---|---|---|
| DLCH | PECVD (ICP-plasma | In. gas (Ar) and C₂H₂, r_{C2H2} = 10-50%, e.g. 15-45%, p: 1 × 10⁻⁴-2 × 10⁻² mbar; ICP-generator 13.56 |
| | source⁺) | MHz, ion current 0.01 to 3.5 mA/cm², plasma density 10⁹-10¹² cm⁻³, ion energy 10 to 70 eV |
| | | (further details DLC see WO 2020/164735, p. 9-10 and table 4) |
| TiZrCx, | React. RF- or DC-puls. or | Inert gas (Ar) and CH₄, r_{CH4} = 5-50%, p: 1 × 10⁻⁴-9 × 10⁻³ mbar, 1-200 kW/cathode⁺⁺, 30-120 |
| TiZrOxCy | DC or AC-MF (co-)sputter.⁺⁺⁺ | kW (further details TM see WO 2020/164735, p.7-9) |
| Si₃N₄ or | React. RF- or DC-pulsed or | N₂ and inert gas (Ar) facultatively, p: 1 × 10⁻⁴-9 × 10⁻³ mbar, Si₃N₄ target + Al-target, or Si₃N₄:Al |
| Si₃N₄:Al | DC or AC-MF (co-)sputter.⁺⁺⁺ | target, 1-200 kW/cathode⁺⁺, 30-120 kW; |
| MeNₓO_{y} | Reactive RF- or DC-pulsed or | Inert gas (Ar) + O₂, metallic (or oxidic) Me-target, |
| | DC or AC-MF sputter. | p: 1 × 10⁻⁴-9 × 10⁻³ mbar, 1-200 kW/cathode⁺⁺, e.g. 3-100 kW, e.g., 3-60 kW; |
| NiCr, TiO_{sub} | React. or not-reactive RF- or | Inert gas (Ar) + O₂ facult., metallic NiCr- or Ti-target, |
| | DC-pulsed or DC or AC-MF | p: 1 × 10⁻⁴-9 × 10⁻³ mbar, 1-200 kW/cathode⁺⁺; NiCr 3-45 kW, e.g. 3-24 kW; |
| | (co-) sputter.⁺⁺⁺ | |
| Ag | RF- or DC-pulsed or DC or | Inert gas (Ar) only, p: 1 × 10⁻⁴-9 × 10⁻³ mbar, Ag-target |
| | AC-MF sputter. | 1-150 kW/cathode⁺⁺ DC, e.g. 3-30 kW. |
| ZnO, SnO₂, | React. RF- or DC-pulsed or | O₂ and inert gas (Ar) facultatively, p: 1 × 10⁻⁴-9 × 10⁻³ mbar, ZnO-, SnO₂-, SnZn-target |
| SnZnO | DC or AC-MF (co-)sputter.⁺⁺⁺ | 1-200 kW/cathode⁺⁺, 20-120 kW, 15-120 kW; |
| optionally | | |
| Al:doped | | |
| Me or Si | React. RF- or DC-pulsed or | O₂ or/and N₂ and inert gas (Ar) facultatively, p: 1 × 10⁻⁴-9 × 10⁻³ mbar, resp. metal or Si₃N₄ |
| oxides, | DC or AC-MF (co-)sputter.⁺⁺⁺ | target, 1-200 kW/cathode⁺⁺; |
| oxynitrides, | | |
| nitrides | | |
| Glas | Cleaning in aqueous solution, | |
| | Rinsing with deionized water | |

⁺Single-turn excitation electrode ICP-plasma sources having coupling windows of 3360 cm² were used for all experiences in an industrial inline coating system, whereat PVD and PECVD processing stations were combined in respective process sequence to process a glass substrate of width of up to 3.21 m and variable length up to 9 m. Three ICP-plasma sources arranged linearly across the substrate width in a distance of 100 to 300 mm window to substrate surface were used at an ICP-power of 1-17 kW per source, which translates to 0.3-5 W/cm² power per area of coupling window.
⁺⁺Planar cathodes with target dimensions l × b = 375 cm × 24 cm, or/and rotatable cathode targets with the length 380 cm were used for all experiences. Cathodes were arranged across the substrate width with a distance of 100-116 mm target to substrate surface, depending on the respective substrate thickness, were used for every PVD-coating station.
⁺⁺⁺(co-)sputter.: means sputtering or co-sputtering.

1. A glass substrate and a solar control layer stack on at least one face of the glass substrate, the solar control layer stack comprising:
at least one IR-reflective coating (II) comprising a silver containing layer (2′);
at least one absorption coating (IV) comprising an optical absorption layer (4) sandwiched and in direct contact to both between two silicon nitride layers (4′, 4″), the absorption layer (4) consisting of a sub-stoichiometric metal nitride MeNₓ, a sub-stoichiometric metal oxide MeO_{y}, or a mixture thereof MeNₓO_{y}, where Me is at least one of an element from the transition metal group V or/and VI of the periodic system of the elements;
a base coating (I) comprising at least one base layer (1) deposited directly on the substrate, and consisting of a silicon nitride or a metal oxide and thereby forming an inner layer of the solar control stack.

2. The glass substrate according to claim 1, wherein the silver containing layer of the IR-reflective coating is sandwiched and in direct contact to both between a ZnO or ZnO:Al layer on the substrate side forming an inner layer of the IR-reflective coating and a NiCr or a TiO₂ layer on the side of the silver containing layer which is directed towards the surface, and a further ZnO, a SnZnO or a SnO₂ layer, or a respective Al-doped layer each in direct contact with the NiCr or the TiO₂ layer and forming an outer layer of the IR-reflecting coating in a direction towards the surface of the layer stack.

3. The glass substrate according to claim 1, wherein the base coating (I) comprises at least one of a nitride or oxide layer (1, 1′) of Si, Ti, Sn, Zn, SnZn, Nb, Zr, or a stack of such nitride or oxide layers different with respect to the metallic and/or semiconductive element(s) in consecutive layers.

4. The glass substrate according to claim 3, wherein the base layer (1) is the inner silicon nitride layer (4′) of the absorption coating (IV).

5. The glass substrate according to claim 1, wherein at least one of the silicon nitride layers (4′, 4″), the ZnO (2), the further ZnO (2′″), the SnZnO (2′″), the SnO₂ (2′″), and/or the nitride or oxide layer of Si, Ti, Sn, Zn, SnZn, Nb, Zr (1, 1′) is an Al-doped layer.

6. The glass substrate according to claim 1, wherein the solar control layer stack further comprises a terminal scratch resistant coating (V), the scratch resistant coating (V) comprising at least a compound layer (5) consisting of the transition metals (TM) titanium and/or zirconium compound with the non-metal(s) oxygen and/or carbon.

7. The glass substrate according to claim 6, wherein the scratch resistant coating (V) consists of a titanium zirconium carbide layer (5) followed in a direction towards the surface and in direct contact to the titanium zirconium carbide layer by a hydrogen containing diamond-like carbon (DLCH) layer (5′).

8. The glass substrate according to claim 6, wherein the scratch resistant coating is a titanium zirconium oxide layer.

9. The glass substrate according to claim 1, wherein the IR-reflective coating follows directly onto the absorption coating.

10. The glass substrate according to claim 6, comprising a further silicon nitride layer sandwiched and in direct contact to both between the terminal layer of the IR-reflecting coating and the scratch resistant coating.

11. The glass substrate according to claim 1, wherein the absorption coating or a further absorption coating follows directly onto the IR-reflective coating or a further IR-reflective coating.

12. The glass substrate according to claim 1, wherein the absorption layer is a sub-stoichiometric metal nitride MeNₓ and the stoichiometric value x is: 0.1<x≤1, especially 0.1≤x≤0.7.

13. The glass substrate according to claim 1, wherein the absorption layer is a sub-stoichiometric metal nitride MeNₓ or a sub-stoichiometric metal oxide MeO_{y}.

14. The glass substrate according to claim 1, wherein Me is one of Mo, Ta, or W or a mixture thereof.

15. The glass substrate according to claim 1, wherein the sub-stoichiometric nitride, oxide or oxynitride is MoNₓO_{y}.

16. The glass substrate according to claim 1, wherein at least one of the two silicon nitride layers and/or the further silicon nitride layer are doped with aluminium.

17. The glass substrate according to claim 1, wherein at least one separating coating (III) is provided between and in direct contact to an IR-reflective coating (II) and the scratch resistant coating (V), between and in direct contact with two consecutive IR-reflective coatings (II), and/or between and in direct contact to an adsorption coating (IV) and an IR-reflective coating (II).

18. The glass substrate according to claim 17, wherein the separating coating (III) comprises or consists of another silicon nitride layer, another zinc oxide layer, another tin oxide, or another zinc tin oxide layer (3, 3′).

19. The glass substrate according to claim 17, wherein the separating coating (III) consists of a silicon nitride layer (3) followed and in direct contact with the zinc tin oxide layer (3′), whereat the silicon nitride layer is in direct contact with the terminal zinc oxide layer of the inner IR-reflective coating and the zinc tin oxide layer is in direct contact with the inner zinc oxide layer of the outer IR-reflecting coating.

20. The glass substrate according to claim 1, wherein the silver containing layer is a silver layer.

21. The glass substrate according to claim 1, wherein the difference Δk=k₇₈₀−k₃₈₀ between the extinction coefficients of the absorption coating measured at 780 nm and at 380 nm is:
$$\vert 0.4 < Δ k < 1. \vert$$

22. The glass substrate according to claim 1, wherein the extinction coefficient k₅₅₀ of the MeNₓO_{y} layer measured at a wavelength of 550 nm is:
$$1.5 < {k}_{550} < 4.2$$

23. The glass substrate according to claim 1, wherein the specific electric resistivity R of the MeNₓO_{y} layer is:
$$R < 600 μΩ * cm$$
